(19) United States
(12) Patent Application Publication
(10) Pub. No.: US 2023/0023073 A1
(43) Pub. Date: Jan. 26, 2023

(54) INPUT/OUTPUT DEVICES THAT ARE COMPATIBLE WITH GATE-ALL-AROUND TECHNOLOGY

(71) Applicant: Synopsys, Inc., Mountain View, CA (US)

(72) Inventors: Victor Moroz, Saratoga, CA (US); Robert B. Lefferts, Portland, OR (US); Xi-Wei Lin, Fremont, CA (US); Munkang Choi, Pleasanton, CA (US)

(73) Assignee: Synopsys, Inc., Mountain View, CA (US)

(21) Appl. No.: 17/870,662

(22) Filed: Jul. 21, 2022

Related U.S. Application Data
(60) Provisional application No. 63/224,741, filed on Jul. 22, 2021.

(51) Int. Cl. H01L 29/423; H01L 27/088; H01L 29/786; H01L 29/66

(52) U.S. Cl. CPC H01L 29/42392; H01L 27/0886; H01L 29/78696; H01L 29/66742

(57) ABSTRACT

An integrated circuit (IC) chip may include a first gate-all-around (GAA) device and a second GAA device. The first GAA device may include a first set of silicon dioxide structures around a first set of silicon channels, a first set of hafnium dioxide structures around the first set of silicon dioxide structures, and a first metal structure around the first set of hafnium dioxide structures. The second GAA device may include a second set of silicon dioxide structures around a second set of silicon channels, and a second metal structure around the second set of silicon dioxide structures. Each silicon dioxide structure in the first set of silicon dioxide structures may have a first thickness. Each silicon dioxide structure in the second set of silicon dioxide structures may have a second thickness, which is greater than the first thickness.

### RELATED APPLICATION

This application claims the benefit of U.S. Provisional Application Ser. No. 63/224,741, filed on 22 Jul. 2021, the contents of which are herein incorporated by reference in their entirety for all purposes.

### TECHNICAL FIELD

The present disclosure relates to semiconductor devices. More specifically, the present disclosure relates to input/output (I/O) devices that are compatible with gate-all-around (GAA) technology.

### BACKGROUND

An increasing demand for computing and storage capacity has fueled an increase in the device density of integrated circuit (IC) designs. The semiconductor manufacturing industry has increased the device density of IC designs by decreasing feature sizes.

### SUMMARY

Embodiments described herein may feature an IC chip which includes logic devices and I/O devices, and which is manufactured using GAA process technology. In some embodiments, the IC chip may include a first GAA device and a second GAA device. The first GAA device may include a first set of silicon dioxide (SiO₂) structures around a first set of silicon (Si) channels, a first set of hafnium dioxide (HfO₂) structures around the first set of SiO₂ structures, and a first metal structure around the first set of HfO₂ structures. The second GAA device may include a second set of SiO₂ structures around a second set of Si channels, and a second metal structure around the second set of SiO₂ structures. Each SiO₂ structure in the first set of SiO₂ structures may have a first thickness, and each SiO₂ structure in the second set of SiO₂ structures may have a second thickness which is greater than the first thickness.

In some embodiments described herein, the first thickness is about 1 nm and the second thickness is about 2.5 nm.

In some embodiments described herein, the first GAA device may implement a logic function and the second GAA device may be part of I/O circuitry. For example, the second GAA device may drive an output pin of the IC chip or receive an input signal from a source which is external to the IC chip.

In some embodiments described herein, the operating voltage range of the second GAA device may be greater than the operating voltage range of the first GAA device.

In some embodiments described herein, the first metal structure and the second metal structure may be made using one or more of titanium nitride (TiN), titanium aluminum nitride (TiAlN), tantalum, tungsten, or lanthanum.

### BRIEF DESCRIPTION OF THE FIGURES

The disclosure can be understood based on the detailed description given below and the accompanying figures. The figures, examples and embodiments are for illustrative purposes, and do not limit the scope of the disclosure. Furthermore, the figures are not necessarily drawn to scale.

FIG. 1 illustrates a logic GAA device and a malformed I/O GAA device fabricated using GAA process technology.

FIG. 2 illustrates an I/O GAA device in accordance with some embodiments described herein.

FIG. 3A-3D illustrate a process for creating a logic device using GAA process technology in accordance with some embodiments described herein.

FIG. 4A-4C illustrate a process for creating an I/O device using GAA process technology in accordance with some embodiments described herein.

FIGS. 5A-5C illustrate a process for creating a logic device and an I/O device on the same IC chip using GAA process technology in accordance with some embodiments described herein.

FIG. 6 illustrates a process for creating logic and I/O GAA devices on an IC chip in accordance with some embodiments described herein.

FIG. 7 illustrates an example flow for the design, verification, and fabrication of an integrated circuit in accordance with some embodiments described herein.

FIG. 8 illustrates an example machine of a computer system within which a set of instructions, for causing the machine to perform any one or more of the methodologies discussed herein, may be executed.

### DETAILED DESCRIPTION

IC designs may contain logic transistors and I/O transistors. Logic transistors may implement the functionality of the IC design and I/O transistors may be used for communicating signals outside the IC design. Examples of logic transistors include, but are not limited to, transistors that are used to implement logic gates (e.g., AND gates, NAND gates, OR gates, NOR gates, XOR gates, and inverters). Examples of I/O transistors include, but are not limited to, transistors that are used to implement a physical layer communication circuit (e.g., a circuit in an IC design that is connected to an external bus).

I/O transistors may have a greater drive strength than logic transistors and may be able to handle higher operating voltage ranges than logic transistors. Although some device structures disclosed herein are in the context of an I/O transistor, the device structures can generally be used to create any transistor that has a greater drive strength than a typical logic transistor and can operate with a higher voltage range than a typical logic transistor.

At advanced complementary metal-oxide-semiconductor (CMOS) technology nodes (e.g., at the 3 nm node and below), logic transistors typically operate at a power supply voltage (Vdd) of less than 1 V, typically in the range of 0.5 V to 0.8 V. I/O transistors may send and/or receive signals which may require the I/O transistor to handle voltages up to 1.5 V.

The term “electrical thickness” of a dielectric material may refer to the physical thickness of a SiO₂ gate that achieves an equivalent capacitance density as the dielectric material. Reducing the physical thickness of the gate dielectric in a transistor may improve performance of the transistors (e.g., increase the switching speed of the transistor) but may make the transistors incompatible with higher voltages. HfO₂ has a higher dielectric constant than SiO₂ (HfO₂ is an example of a high-K dielectric). Thus, the electrical thickness of an HfO₂ layer may be substantially less than its physical thickness. An SiO₂ layer and an HfO₂ layer may be used in combination to achieve the desired performance and operating voltage range characteristics.

In fin field-effect transistor (FinFET) technology, logic devices may have a small electrical thickness of the gate dielectric for FinFETs that operate at a Vdd of under 1 V. Typically, a gate dielectric may have a 1.0 nm SiO₂ layer and a 1.5 nm HfO₂ layer. I/O FinFETs have several differences with respect to logic FinFETs. Specifically, I/O FinFETs have a longer channel length. For example, a typical logic transistor has a channel length that is about CPP/3, where CPP is the gate pitch (CPP is an abbreviation of “Contacted Poly Pitch”). On the other hand, the channel length of an I/O FinFET is usually CPP×1.3. The longer channel length reduces short channel effects such as Drain Induced Barrier Lowering (DIBL) and avoids transistor leakage due to the “punch-through” effect at higher voltages. I/O FinFETs also have less steep source/drain (S/D) junctions to avoid avalanche breakdown and Band-To-Band-Tunneling (BTBT) that is necessary at higher voltages. Another feature of the I/O FinFETs is that it has a thicker SiO₂ layer, which is typically 3.2 nm at 7 nm node, and gradually reduces as the I/O voltage slowly scales down from 3.3 V to 2.5 V to 1.8 V to 1.5 V.

A logic FinFET and an I/O FinFET may include a silicon (Si) layer, an SiO₂ layer, a HfO₂ layer, and a TiN layer. The gate of the FinFET device may be formed by the TiN layer. The width of the conducting channel in the Si layer may be controlled by the gate voltage. The SiO₂ and HfO₂ dielectric layers may separate the Si layer from the TiN gate. The gate dielectric in logic FinFETs may have a thin electrical thickness that provides the logic FinFET with better gate control, but typically restricts the operating voltage (Vdd) to less than 1 V. On the other hand, the electrical thickness of the gate dielectric in an I/O FinFET may be greater than the electrical thickness of the gate dielectric in a logic FinFET. The greater electrical thickness in I/O FinFETs may enable the I/O FinFETs to handle higher voltages than the logic FinFETs. In FinFET process technology, a thicker gate dielectric may be formed by spacing the I/O fins wider than the logic fins. The term “process technology” or “technology” may refer to the manufacturing or fabrication method that is used for making IC chips.

The approach used by FinFET process technology for creating logic transistors and I/O transistors on the same IC chip may not work for GAA transistors fabricated using GAA process technology.

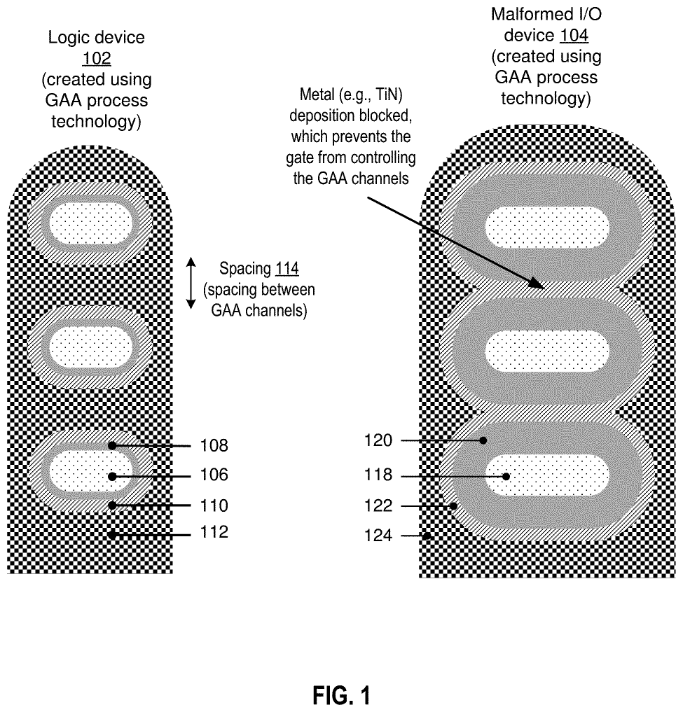

FIG. 1 illustrates a logic GAA device and a malformed I/O GAA device fabricated using GAA process technology.

Logic device 102 may be created using GAA process technology and may include Si structure 106 (the terms “structure” or “layer” may be used interchangeably when describing a semiconductor device), SiO₂ structure 108 around Si structure 106, HfO₂ structure 110 around SiO₂ structure 108, and TiN structure 112 that surrounds HfO₂ structure 110. The gate of logic GAA device 102 may be formed by TiN structure 112. The width of the conducting channel (also referred to as the “GAA channel”) in Si structure 106 may be controlled by the gate voltage. The SiO₂ structure 108 and HfO₂ structure 110 are dielectrics that separate Si structure 106 (i.e., the GAA channel) from the gate, i.e., TiN structure 112. A GAA channel may be created using other semiconductor materials instead of Si. Examples of other semiconductor materials that may be used to create the GAA channels include, but are not limited to, silicon-germanium (SiGe), germanium (Ge), and gallium nitride (GaN).

In GAA process technology, the spacing between the stacked GAA channels may be defined by a blanket epitaxy that may apply to the entire wafer. Spacing 114 between GAA channels is designed to be small to reduce the parasitic gate-to-drain capacitance that is directly proportional to the spacing 114. Therefore, there may be insufficient space for creating a thicker gate dielectric in between the GAA channels if an I/O GAA device is attempted to be manufactured in the same manner as a logic GAA device.

For example, malformed I/O device 104 illustrates a structure that may be created if an I/O GAA device with a thicker dielectric structure is attempted to be manufactured in the same manner as logic device 102. Specifically, if the same high-κ dielectric structure (e.g., a HfO₂ structure) that was used in logic device 102 is deposited on a thicker SiO₂ layer as required for I/O devices operating at higher voltages, then there may not be enough room left for depositing a functional metal gate. In other words, the “gate all around” structure is not achieved, which is shown by malformed I/O device 104.

Specifically, Si structure 118 may form the GAA channel, SiO₂ structure 120 may be created around Si structure 118, and HfO₂ structure 122 may be created around SiO₂ structure 120. However, as shown in malformed I/O device 104, the HfO₂ structures (e.g., HfO₂ structure 122) corresponding to adjacent GAA channels may touch each other, which may block metal deposition in the spacing between the GAA channels. Thus, the TiN structure 124 may not surround each individual GAA channel, which may prevent the gate from controlling the GAA channels. In other words, in malformed I/O device 104, the gate is unable to control the entire width of the GAA channels, and the resulting I/O device is dysfunctional.

One possible solution is to create two types of devices on the same chip: GAA devices for function logic and FinFET devices with a thicker dielectric layer for I/O. However, this approach may substantially increase the complexity and manufacturing costs of the process technology. Another approach is to place FinFET I/O devices on a different IC chip. However, this approach may use additional circuitry to buffer and communicate information between multiple chips, which may increase power, area, and cost of the system.

Some embodiments described herein feature an I/O device that is compatible with GAA technology. Specifically, some embodiments described herein feature an IC chip that includes logic GAA devices and I/O GAA devices created using a GAA process technology. Some embodiments described herein feature a method for using GAA process technology to create an IC chip that includes logic GAA devices and I/O GAA devices.

The HfO₂ layer has a high dielectric constant and is important for achieving superior gate control for logic transistors that operate with high performance at low voltages (i.e., low Vdd transistors). However, the HfO₂ dielectric layer is ineffective at high voltages and the standard high-κ metal gate (HKMG) stack is not suited to handle the typical voltages used in I/O devices. On the other hand, a 2.5 nm thick SiO₂ gate dielectric layer (which typically contains 5% to 20% nitrogen) can handle the typical voltages used in I/O devices.

In some embodiments described herein, the HfO₂ structure is omitted when fabricating I/O GAA devices and the entire dielectric structure is made of SiO₂.

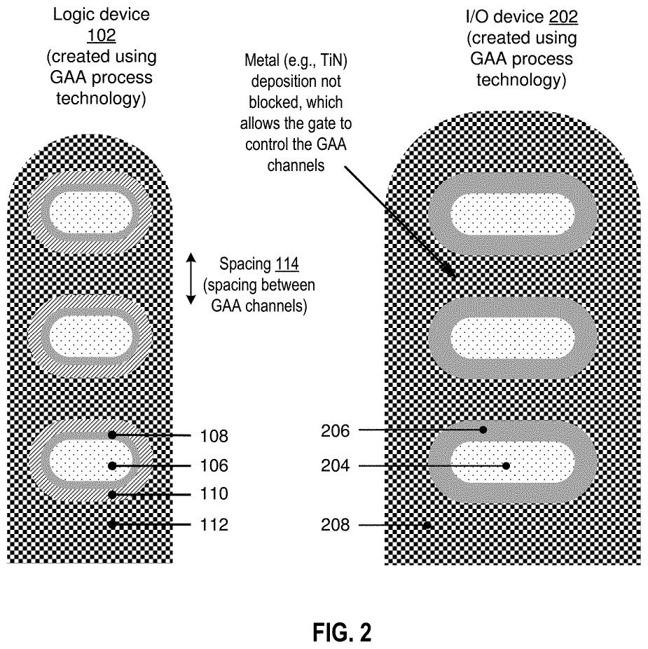

FIG. 2 illustrates an I/O GAA device in accordance with some embodiments described herein.

I/O device 202 may be created using GAA process technology and may include Si structure 204, SiO₂ structure 206 around Si structure 204, and TiN structure 208 that surrounds SiO₂ structure 206. The gate of I/O device 202 may be formed by TiN structure 208, which surrounds each individual GAA channel (e.g., Si structure 204). Thus, the entire widths of the GAA channels in I/O device 202 may be controlled by the gate voltage.

Logic device 102 from FIG. 1 is also shown in FIG. 2 for comparison purposes. I/O device 202 includes an SiO₂ structure (e.g., SiO₂ structure 206) but does not include an HfO₂ structure around the SiO₂ structure. The metal structure in logic device 102 and I/O device 202 may be made of TiN. Other materials that may be used in combination with TiN include, but are not limited to, TiAlN, tantalum (Ta), tungsten (W), and lanthanum (La).

Specifically, in some embodiments, the SiO₂ dielectric structure (e.g., SiO₂ structure 206) around the GAA channel is about 2.5 nm thick. A non-obvious insight for using a thicker SiO₂ structure and omitting the HfO₂ structure in the gate stack of an I/O device is based on the exponential dependence of the leakage current through the gate dielectric versus its thickness. Specifically, a GAA device with a 2.5 nm thick SiO₂ layer is expected to satisfy the operating voltage requirements and gate leakage current requirements for an I/O device.

I/O devices disclosed herein (e.g., I/O device 202) may have a smaller area than comparable I/O FinFET devices. Specifically, the area of a I/O GAA device may be half that of a comparable I/O FinFET device under the following assumptions: (1) driving strength is measured per μm layout width, (2) off-state leakage is 1 nA per μm layout width, (3) power supply voltage is 1.2 V, (4) fin-to-fin spacing and GAA-to-GAA spacing are 25 nm, (5) GAA devices have 3 stacked channels, (6) fin width and GAA thickness are 5 nm, and (7) fin height is 50 nm.

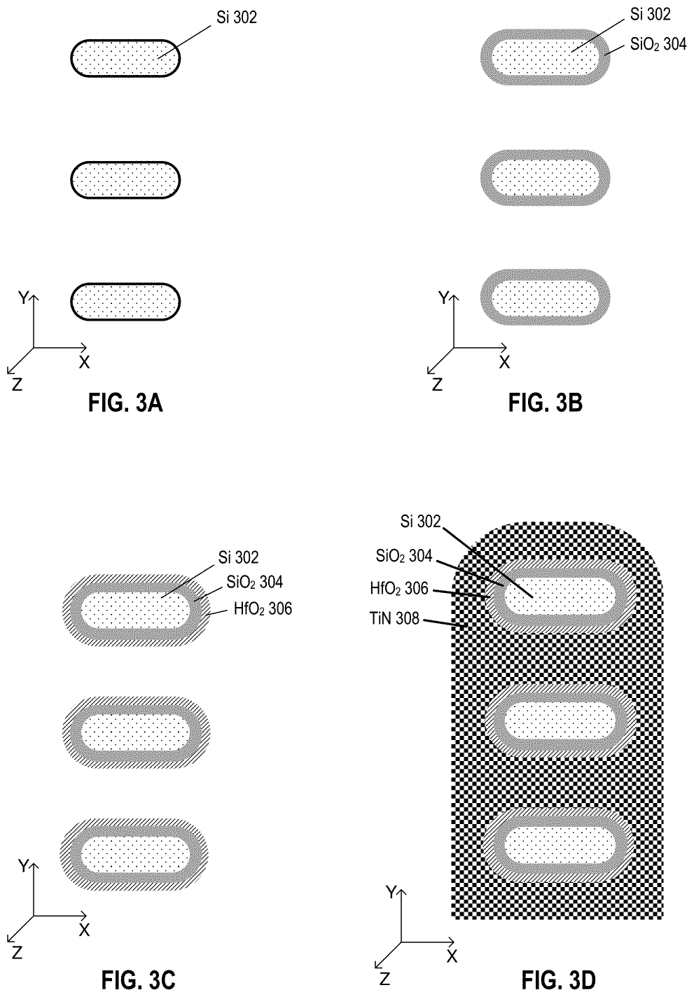

FIG. 3A-3D illustrate a process for creating a logic device using GAA process technology in accordance with some embodiments described herein.

As shown in FIG. 3A, an initial structure may be created that has several stacked and exposed Si channels, e.g., Si channel 302. Each Si channel may extend in a Z-direction (which is perpendicular to the drawing page) and may be physically supported by structures at the two ends of the Si channel (the structures physically supporting the Si channels are not shown in FIGS. 3A-3D). The channel current of the logic device which is controlled by the gate may flow through the Si channel in the Z-direction.

As shown in FIG. 3B, about 1.0 nm of SiO₂ may be deposited using atomic layer deposition (ALD) to create SiO₂ structures around the Si structures (e.g., SiO₂ structure 304 around Si channel 302). As shown in FIG. 3C, about 1.5 nm of HfO₂ may be deposited using ALD to create HfO₂ structures around the SiO₂ structures (e.g., HfO₂ structure 306 around SiO₂ structure 304). Next, as shown in FIG. 3D, a metal gate structure may be created around the HfO₂ structures using ALD (e.g., TiN structure 308 around the HfO₂ structures).

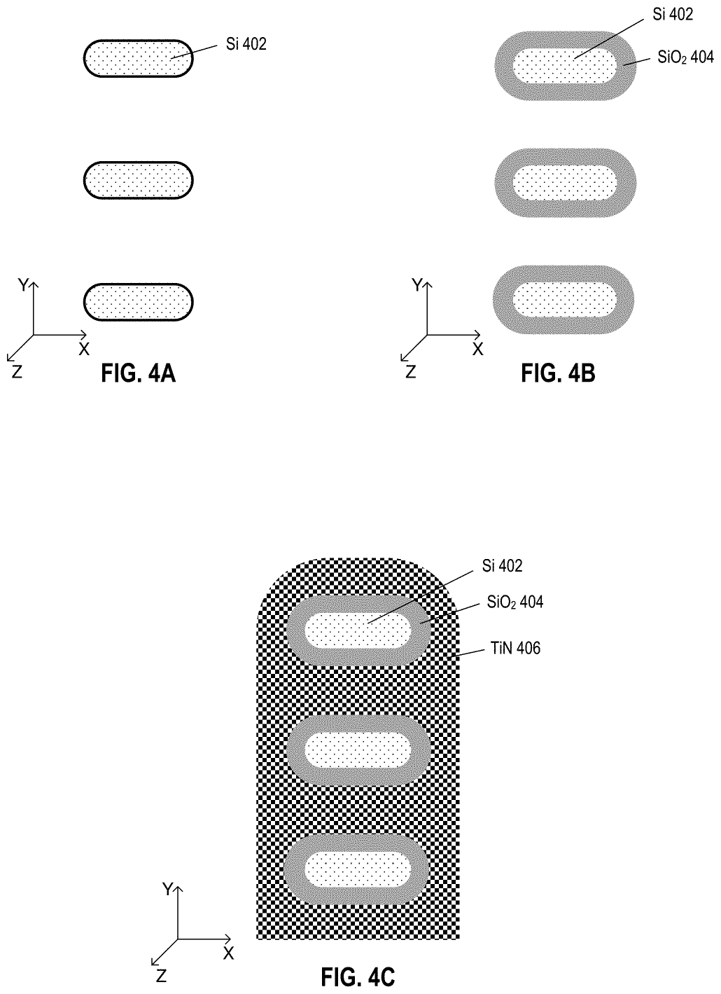

FIG. 4A-4C illustrate a process for creating an I/O device using GAA process technology in accordance with some embodiments described herein.

In FIG. 4A, an initial structure may be created that has several stacked and exposed Si channels, e.g., Si channel 402. Each Si channel may extend in a Z-direction (which is perpendicular to the drawing page) and may be physically supported by structures at the two ends of the Si channel (the structures physically supporting the Si channels are not shown in FIGS. 4A-4C). The channel current of the I/O device which is controlled by the gate may flow through the Si channel in the Z-direction.

As shown in FIG. 4B, about 2.5 nm of SiO₂ may be deposited to create SiO₂ structures around the Si channels (e.g., SiO₂ structure 404 around Si structure 402) using ALD. Next, as shown in FIG. 4C, a metal gate structure may be created around the SiO₂ structures using ALD (e.g., TiN structure 406 around the SiO₂ structures).

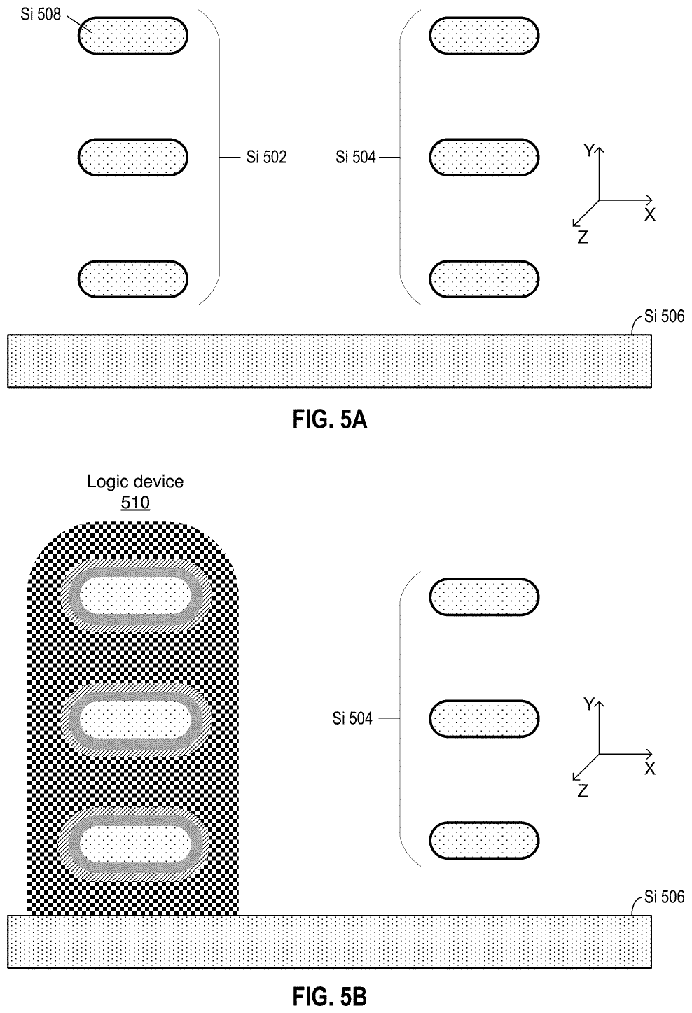

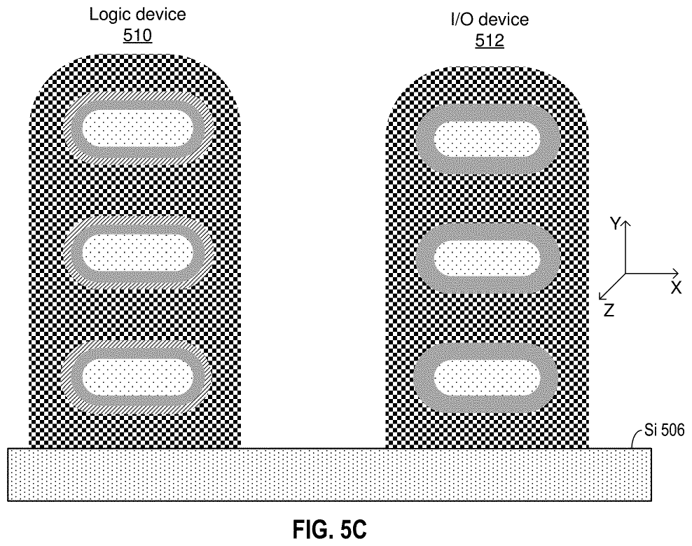

FIGS. 5A-5C illustrate a process for creating a logic device and an I/O device on the same IC chip using GAA process technology in accordance with some embodiments described herein.

As shown in FIG. 5A, a first set of Si structures 502 and a second set of Si structures 504 may be created on Si substrate 506. Each set of Si structures may include several stacked and exposed Si channels (e.g., Si channel 508). Each Si channel may extend in a Z-direction (which is perpendicular to the drawing page) and may be physically supported by structures at the two ends of the Si channel (the structures physically supporting the Si channels are not shown in FIGS. 5A-5C). The channel currents of the GAA devices which are controlled by their respective gates may flow through the Si channels in the Z-direction.

Next, logic devices in the IC chip may be created. Specifically, areas of the IC chip that include I/O devices may be masked when creating logic devices. As shown in FIG. 5B, logic device 510 may be created in an unmasked area of the IC chip using the process shown in FIGS. 3A-3D. When logic device 510 is created, no deposition occurs on second set of Si structures 504 because second set of Si structures 504 may be in an I/O device area which may be masked when logic device 510 is created.

I/O devices may then be created in the IC chip. Specifically, areas of the IC chip that include logic devices may be masked when creating I/O devices. As shown in FIG. 5C, I/O device 512 may be created in an unmasked area of the IC chip using the process shown in FIGS. 4A-4C. When I/O device 512 is created, no deposition may occur on logic device 510 because that area may be masked.

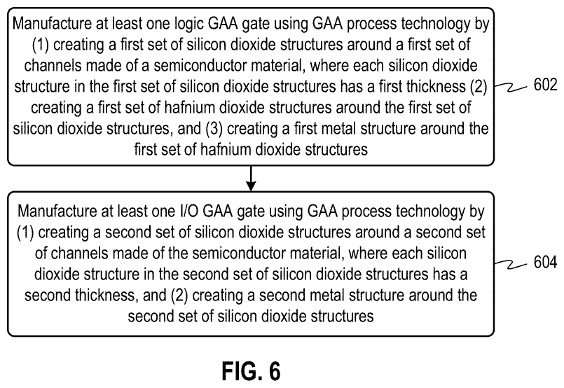

FIG. 6 illustrates a process for creating logic and I/O GAA devices on an IC chip in accordance with some embodiments described herein.

At least one logic GAA gate may be manufactured using GAA process technology by (1) creating a first set of SiO₂ structures around a first set of channels made of a semiconductor material, where each SiO₂ structure in the first set of SiO₂ structures has a first thickness, (2) creating a first set of HfO₂ structures around the first set of SiO₂ structures, and (3) creating a first metal structure around the first set of HfO₂ structures (at 602). Examples of semiconductor materials that may be used to create channels include, but are not limited to, Si, SiGe, Ge, and GaN.

Next, at least one I/O GAA gate may be manufactured using GAA process technology by (1) creating a second set of SiO₂ structures around a second set of channels made of the semiconductor material, where each SiO₂ structure in the second set of SiO₂ structures has a second thickness, and (2) creating a second metal structure around the second set of SiO₂ structures (at 604). In some embodiments described herein, the second thickness may be greater than the first thickness. Some embodiments described herein may feature software applications to help design, simulate, test, and/or manufacture logic GAA devices and I/O GAA devices on the same IC chip.

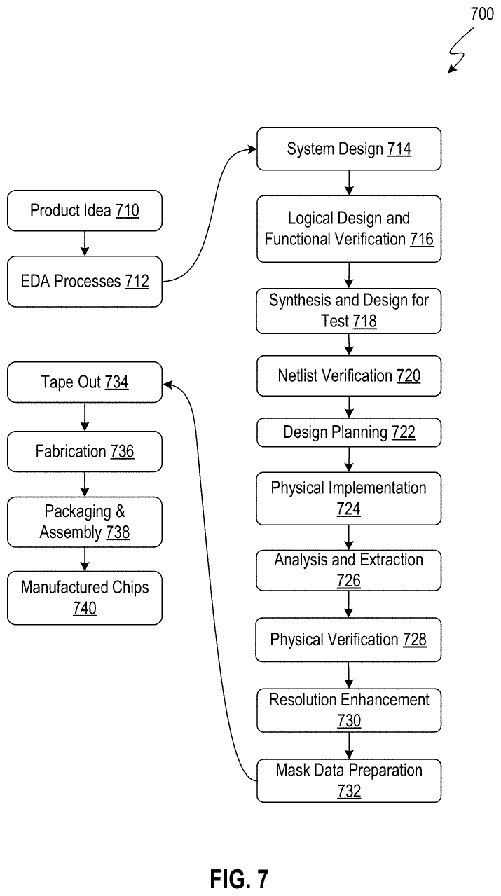

FIG. 7 illustrates an example flow for the design, verification, and fabrication of an integrated circuit in accordance with some embodiments described herein.

EDA processes 712 (the acronym “EDA” refers to “Electronic Design Automation”) can be used to transform and verify design data and instructions that represent the integrated circuit. Each of these processes can be structured and enabled as multiple modules or operations.

Flow 700 can start with the creation of a product idea 710 with information supplied by a designer, information which is transformed and verified by using EDA processes 712. When the design is finalized, the design is taped-out 734, which is when artwork (e.g., geometric patterns) for the integrated circuit is sent to a fabrication facility to manufacture the mask set, which is then used to manufacture the integrated circuit. After tape-out, a semiconductor die is fabricated 736 and packaging and assembly 738 are performed to produce the manufactured IC chip 740.

Specifications for a circuit or electronic structure may range from low-level transistor material layouts to high-level description languages. A high-level of representation may be used to design circuits and systems, using a hardware description language (“HDL”) such as VHDL, Verilog, SystemVerilog, SystemC, MyHDL or OpenVera. The HDL description can be transformed to a logic-level register transfer level (“RTL”) description, a gate-level description, a layout-level description, or a mask-level description. Each lower representation level that is a more concrete description adds more detail into the design description. The lower levels of representation that are more concrete descriptions can be generated by a computer, derived from a design library, or created by another design automation process. An example of a specification language at a lower level of representation language for specifying more detailed descriptions is SPICE (which stands for “Simulation Program with Integrated Circuit Emphasis”). Descriptions at each level of representation contain details that are sufficient for use by the corresponding tools of that layer (e.g., a formal verification tool).

During system design 714, functionality of an integrated circuit to be manufactured is specified. The design may be optimized for desired characteristics such as power consumption, performance, area (physical and/or lines of code), and reduction of costs, etc. Partitioning of the design into different types of modules or components can occur at this stage.

During logic design and functional verification 716, modules or components in the circuit are specified in one or more description languages and the specification is checked for functional accuracy. For example, the components of the circuit may be verified to generate outputs that match the requirements of the specification of the circuit or system being designed. Functional verification may use simulators and other programs such as test-bench generators, static HDL checkers, and formal verifiers. In some embodiments, special systems of components referred to as ‘emulators’ or ‘prototyping systems’ are used to speed up the functional verification.

During synthesis and design for test 718, HDL code is transformed to a netlist. In some embodiments, a netlist may be a graph structure where edges of the graph structure represent components of a circuit and where the nodes of the graph structure represent how the components are interconnected. Both the HDL code and the netlist are hierarchical articles of manufacture that can be used by an EDA product to verify that the integrated circuit, when manufactured, performs according to the specified design. The netlist can be optimized for a target semiconductor manufacturing technology. Additionally, the finished integrated circuit may be tested to verify that the integrated circuit satisfies the requirements of the specification.

During netlist verification 720, the netlist is checked for compliance with timing constraints and for correspondence with the HDL code. During design planning 722, an overall floor plan for the integrated circuit is constructed and analyzed for timing and top-level routing.

During layout or physical implementation 724, physical placement (positioning of circuit components such as transistors or capacitors) and routing (connection of the circuit components by multiple conductors) occurs, and the selection of cells from a library to enable specific logic functions can be performed. As used herein, the term ‘cell’ may specify a set of transistors, other components, and interconnections that provides a Boolean logic function (e.g., AND, OR, NOT, XOR) or a storage function (such as a flip-flop or latch). As used herein, a circuit ‘block’ may refer to two or more cells. Both a cell and a circuit block can be referred to as a module or component and are enabled as both physical structures and in simulations. Parameters are specified for selected cells (based on ‘standard cells’) such as size and made accessible in a database for use by EDA products.

During analysis and extraction 726, the circuit function is verified at the layout level, which permits refinement of the layout design. During physical verification 728, the layout design is checked to ensure that manufacturing constraints are correct, such as DRC constraints, electrical constraints, lithographic constraints, and that circuitry function matches the HDL design specification. During resolution enhancement 730, the geometry of the layout is transformed to improve how the circuit design is manufactured.

During tape-out, data is created to be used (after lithographic enhancements are applied if appropriate) for production of lithography masks. During mask data preparation 732, the ‘tape-out’ data is used to produce lithography masks that are used to produce finished integrated circuits.

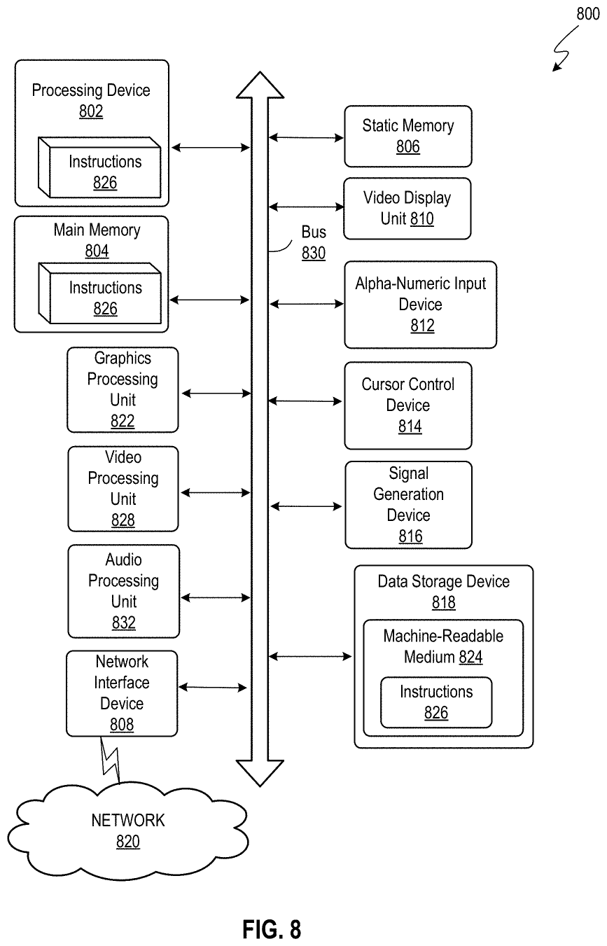

A storage subsystem of a computer system (such as computer system 800 in FIG. 8) may be used to store the programs and data structures that are used by some or all of the EDA products described herein, and products used for development of cells for the library and for physical and logical design that use the library.

FIG. 8 illustrates an example machine of a computer system 800 within which a set of instructions, for causing the machine to perform any one or more of the methodologies discussed herein, may be executed.

In alternative implementations, the machine may be connected (e.g., networked) to other machines in a LAN, an intranet, an extranet, and/or the Internet. The machine may operate in the capacity of a server or a client machine in client-server network environment, as a peer machine in a peer-to-peer (or distributed) network environment, or as a server or a client machine in a cloud computing infrastructure or environment.

The machine may be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 800 includes a processing device 802, a main memory 804 (e.g., read-only memory (ROM), flash memory, dynamic random access memory (DRAM) such as synchronous DRAM (SDRAM), a static memory 806 (e.g., flash memory, static random access memory (SRAM), etc.), and a data storage device 818, which communicate with each other via a bus 830.

Processing device 802 represents one or more processors such as a microprocessor, a central processing unit, or the like. More particularly, the processing device may be complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 802 may also be one or more special-purpose processing devices such as an application specific integrated circuit (ASIC), a field programmable gate array (FPGA), a digital signal processor (DSP), network processor, or the like. The processing device 802 may be configured to execute instructions 826 for performing the operations and steps described herein.

The computer system 800 may further include a network interface device 808 to communicate over the network 820. The computer system 800 also may include a video display unit 810 (e.g., a liquid crystal display (LCD) or a cathode ray tube (CRT)), an alphanumeric input device 812 (e.g., a keyboard), a cursor control device 814 (e.g., a mouse), a graphics processing unit 822, a signal generation device 816 (e.g., a speaker), graphics processing unit 822, video processing unit 828, and audio processing unit 832.

The data storage device 818 may include a machine-readable storage medium 824 (also known as a non-transitory computer-readable medium) on which is stored one or more sets of instructions 826 or software embodying any one or more of the methodologies or functions described herein. The instructions 826 may also reside, completely or at least partially, within the main memory 804 and/or within the processing device 802 during execution thereof by the computer system 800, the main memory 804 and the processing device 802 also constituting machine-readable storage media.

In some implementations, the instructions 826 include instructions to implement functionality corresponding to the present disclosure. While the machine-readable storage medium 824 is shown in an example implementation to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine and the processing device 802 to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm may be a sequence of operations leading to a desired result. The operations are those requiring physical manipulations of physical quantities. Such quantities may take the form of electrical or magnetic signals capable of being stored, combined, compared, and otherwise manipulated. Such signals may be referred to as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the present disclosure, it is appreciated that throughout the description, certain terms refer to the action and processes of a computer system, or similar electronic computing device, that manipulates and transforms data represented as physical (electronic) quantities within the computer system's registers and memories into other data similarly represented as physical quantities within the computer system memories or registers or other such information storage devices.

The present disclosure also relates to an apparatus for performing the operations herein. This apparatus may be specially constructed for the intended purposes, or it may include a computer selectively activated or reconfigured by a computer program stored in the computer. Such a computer program may be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various other systems may be used with programs in accordance with the teachings herein, or it may prove convenient to construct a more specialized apparatus to perform the method. In addition, the present disclosure is not described with reference to any particular programming language. It will be appreciated that a variety of programming languages may be used to implement the teachings of the disclosure as described herein.

The present disclosure may be provided as a computer program product, or software, that may include a machine-readable medium having stored thereon instructions, which may be used to program a computer system (or other electronic devices) to perform a process according to the present disclosure. A machine-readable medium includes any mechanism for storing information in a form readable by a machine (e.g., a computer). For example, a machine-readable (e.g., computer-readable) medium includes a machine (e.g., a computer) readable storage medium such as a read only memory (“ROM”), random access memory (“RAM”), magnetic disk storage media, optical storage media, flash memory devices, etc.

In the foregoing disclosure, implementations of the disclosure have been described with reference to specific example implementations thereof. It will be evident that various design modifications may be made thereto without departing from the broader spirit and scope of implementations of the disclosure as set forth in the following claims. Where the disclosure refers to some elements in the singular tense, more than one element can be depicted in the figures and like elements are labeled with like numerals. The disclosure and drawings are, accordingly, to be regarded in an illustrative sense rather than a restrictive sense.

What is claimed is:

1. An integrated circuit (IC) chip, comprising:
a first gate-all-around (GAA) device comprising:
a first set of silicon dioxide structures around a first set of silicon channels, wherein each silicon dioxide structure in the first set of silicon dioxide structures has a first thickness,
a first set of hafnium dioxide structures around the first set of silicon dioxide structures, and
a first metal structure around the first set of hafnium dioxide structures; and
a second GAA device comprising:
a second set of silicon dioxide structures around a second set of silicon channels, wherein each silicon dioxide structure in the second set of silicon dioxide structures has a second thickness, and
a second metal structure around the second set of silicon dioxide structures.

2. The IC chip of claim 1, wherein the second thickness is greater than the first thickness.

3. The IC chip of claim 2, wherein the first thickness is about 1 nm.

4. The IC chip of claim 2, wherein the second thickness is about 2.5 nm.

5. The IC chip of claim 1, wherein the first GAA device implements a logic function.

6. The IC chip of claim 1, wherein the second GAA device drives an output pin of the IC chip.

7. The IC chip of claim 1, wherein the second GAA device receives an input signal from a source which is external to the IC chip.

8. The IC chip of claim 1, wherein a second operating voltage range of the second GAA device is greater than a first operating voltage range of the first GAA device.

9. The IC chip of claim 1, wherein the first metal structure and the second metal structure are made of titanium nitride.

10. The IC chip of claim 1, wherein the first metal structure and the second metal structure are made of titanium aluminum nitride.

11. The IC chip of claim 1, wherein the first metal structure and the second metal structure are made of tantalum.

12. The IC chip of claim 1, wherein the first metal structure and the second metal structure are made of tungsten.

13. The IC chip of claim 1, wherein the first metal structure and the second metal structure are made of lanthanum.

14. An integrated circuit (IC) manufactured using gate-all-around (GAA) process technology, the IC comprising:
a first GAA transistor, comprising:
a first set of channels made of a semiconductor material,
a first set of silicon dioxide structures around the set of channels, wherein each silicon dioxide structure in the first set of silicon dioxide structures has a first thickness,
a first set of hafnium dioxide structures around the first set of silicon dioxide structures, and
a first metal structure around the first set of hafnium dioxide structures, wherein a current flowing through the first set of channels is controlled by a first voltage which is applied to the first metal structure; and
a second GAA transistor, comprising:
a second set of channels made of the semiconductor material,
a second set of silicon dioxide structures around the second set of channels, wherein each silicon dioxide structure in the second set of silicon dioxide structures has a second thickness, which is greater than the first thickness, and
a second metal structure around the second set of silicon dioxide structures, wherein a current flowing through the second set of channels is controlled by a second voltage which is applied to the second metal structure.

15. The IC of claim 14, wherein a second operating voltage range of the second GAA transistor is greater than a first operating voltage range of the first GAA transistor.

16. The IC of claim 14, wherein the first thickness is about 1 nm, and wherein the second thickness is about 2.5 nm.

17. The IC of claim 14, wherein the first metal structure and the second metal structure are made of a material selected from a group comprising titanium nitride, titanium aluminum nitride, tantalum, tungsten, and lanthanum.

18. The IC of claim 14, wherein the first GAA transistor is in an area of the IC that includes logic circuitry.

19. The IC of claim 14, wherein the second GAA transistor is in an area of the IC that includes input/output (I/O) circuitry.

20. A method, comprising:
manufacturing a first gate-all-around (GAA) device on a silicon substrate, comprising:
creating a first set of silicon dioxide structures around a first set of silicon channels, wherein each silicon dioxide structure in the first set of silicon dioxide structures has a first thickness,
creating a first set of hafnium dioxide structures around the first set of silicon dioxide structures, and
creating a first metal structure around the first set of hafnium dioxide structures; and
manufacturing a second GAA device on the silicon substrate, comprising:
creating a second set of silicon dioxide structures around a second set of silicon channels, wherein each silicon dioxide structure in the second set of silicon dioxide structures has a second thickness which is greater than the first thickness, and
creating a second metal structure around the second set of silicon dioxide structures.
